(19) United States
(12) Patent Application Publication
(10) Pub. No.: US 2025/0221319 A1
(43) Pub. Date: Jul. 3, 2025

(54) METHOD FOR MANUFACTURING MAGNETORESISTANCE EFFECT ELEMENT AND MAGNETORESISTANCE EFFECT ELEMENT

(71) Applicant: TDK Corporation, Tokyo (JP)

(72) Inventor: Eiji KOMURA, Tokyo (JP)

(73) Assignee: TDK Corporation, Tokyo (JP)

(21) Appl. No.: 19/081,178

(22) Filed: Mar. 17, 2025

Related U.S. Application Data
(63) Continuation of application No. PCT/JP2022/035871, filed on Sep. 27, 2022.

(51) Int. Cl. H10N 50/80; H10B 61/00; H10N 50/01; H10N 50/10

(52) U.S. Cl. CPC H10N 50/80; H10B 61/20; H10N 50/01; H10N 50/10

(57) ABSTRACT

This method for manufacturing a magnetoresistance effect element has a measurement step, a comparison step, and a determination step. In the measurement step, a laminate including a first detection layer and a second detection layer is etched, and a first measurement time from detection of a first signal derived from a first material included in the first detection layer to detection of a second signal derived from a second material included in the second detection layer is measured. In the comparison step, a first reference time from detection of the first signal to detection of the second signal during etching of a reference laminate having the same film constitution as the laminate is compared with the first measurement time, and a deviation between the first reference time and the first measurement time is obtained. In the determination step, conditions from detection of the second signal to ending of etching are determined based on the deviation.

### CROSS-REFERENCE TO RELATED APPLICATION

The present application is a continuation of PCT/JP2022/035871, filed on Sep. 27, 2022, the entire contents of which are incorporated herein by reference.

### TECHNICAL FIELD

The present disclosure relates to a method for manufacturing a magnetoresistance effect element and a magnetoresistance effect element.

### BACKGROUND ART

Giant magnetoresistance (GMR) elements constituted of a multilayer film having ferromagnetic layers and a nonmagnetic layer, and tunnel magnetoresistance (TMR) elements using an insulating layer (a tunnel barrier layer, a barrier layer) as a nonmagnetic layer are known as magnetoresistance effect elements. Magnetoresistance effect elements can be applied to magnetic sensors, high-frequency components, magnetic heads, and magnetic random access memories (MRAM).

An MRAM is a storage element in which a magnetoresistance effect element is integrated. An MRAM allows reading and writing of data utilizing characteristics of magnetoresistance effect elements whose resistance varies if magnetization directions of two ferromagnetic layers sandwiching a nonmagnetic layer (barrier layer) therebetween in a magnetoresistance effect element vary. For example, the magnetization directions of ferromagnetic layers are controlled utilizing a magnetic field generated by a current. In addition, for example, the magnetization directions of ferromagnetic layers are controlled utilizing a spin transfer torque (STT) generated when a current flows in a lamination direction of a magnetoresistance effect element.

When the magnetization directions of ferromagnetic layers are rewritten utilizing an STT, a current is caused to flow in a lamination direction of a magnetoresistance effect element. A writing current may cause deterioration in characteristics of the magnetoresistance effect element.

In recent years, attention has been focused on methods requiring no current to flow in a lamination direction of a magnetoresistance effect element at the time of writing. One of the methods is a writing method utilizing a spin-orbit torque (SOT) (for example, Patent Document 1). An SOT is induced due to a spin current generated by a spin-orbit interaction or a Rashba effect in an interface between different kinds of materials. A current for inducing an SOT into a magnetoresistance effect element flows in a direction intersecting the lamination direction of the magnetoresistance effect element. That is, there is no need for a current to flow in the lamination direction of the magnetoresistance effect element, and thus an extended lifespan of the magnetoresistance effect element is expected.

### CITATION LIST

### Patent Document

Patent Document 1: Japanese Unexamined Patent Application, First Publication No. 2017-216286

### SUMMARY OF INVENTION

### Technical Problem

A magnetoresistance effect element using an SOT has a wiring layer generating a spin current, and a laminate in which magnetoresistance change occurs. The laminate is processed to have a predetermined shape and comes into contact with the wiring layer. The laminate is processed to have a predetermined shape by etching using an ion beam or the like. Etching conditions may vary depending on various factors, such as a cause attributable to an output side, such as dirt adhering to an ion beam source, or a cause attributable to an irradiation object, such as film quality of films constituting the laminate. If etching proceeds more than necessary, it may affect the performance of a magnetoresistance effect element.

The present disclosure has been made in consideration of the foregoing circumstances, and an object thereof is to provide a method for manufacturing a magnetoresistance effect element in which progress of excessive etching can be curbed, and a magnetoresistance effect element produced by the manufacturing method.

### Solution to Problem

In order to resolve the foregoing problems, the present disclosure provides the following means.

A method for manufacturing a magnetoresistance effect element according to a first aspect has a measurement step, a comparison step, and a determination step. In the measurement step, a laminate including a first detection layer and a second detection layer is etched, and a first measurement time from detection of a first signal derived from a first material included in the first detection layer to detection of a second signal derived from a second material included in the second detection layer is measured. In the comparison step, a first reference time from detection of the first signal to detection of the second signal during etching of a reference laminate having the same film constitution as the laminate is compared with the first measurement time, and a deviation between the first reference time and the first measurement time is obtained. In the determination step, conditions from detection of the second signal to ending of etching are determined based on the deviation.

### Advantageous Effects of Invention

In the method for manufacturing a magnetoresistance effect element according to the present disclosure, progress of excessive etching can be curbed. In addition, in the magnetoresistance effect element produced by the method for manufacturing a magnetoresistance effect element according to the present disclosure, heat is unlikely to be generated.

### BRIEF DESCRIPTION OF DRAWINGS

FIG. 1 A flowchart of a method for manufacturing a magnetoresistance effect element according to a first embodiment.

FIG. 2 An example of a cross-sectional view of a magnetoresistance effect element produced by the method for manufacturing a magnetoresistance effect element according to the first embodiment.

FIG. 3 An example of a plan view of the magnetoresistance effect element produced by the method for manufacturing a magnetoresistance effect element according to the first embodiment.

FIG. 4 An explanatory schematic view of the method for manufacturing a magnetoresistance effect element according to the first embodiment.

FIG. 5 Another explanatory schematic view of the method for manufacturing a magnetoresistance effect element according to the first embodiment.

FIG. 6 Another explanatory schematic view of the method for manufacturing a magnetoresistance effect element according to the first embodiment.

FIG. 7 A circuit diagram of a magnetic array according to the first embodiment.

FIG. 8 A cross-sectional view of a part in the vicinity of the magnetoresistance effect element of the magnetic array according to the first embodiment.

FIG. 9 A cross-sectional view of a magnetoresistance effect element according to a first modification example.

### DESCRIPTION OF EMBODIMENT

Hereinafter, the present embodiment will be described in detail suitably with reference to the drawings. In the drawings used in the following description, in order to make characteristics easy to understand, characteristic portions may be shown in an enlarged manner for the sake of convenience, and dimensional ratios or the like of each constituent element may differ from actual values thereof. Materials, dimensions, and the like shown in the following description are merely exemplary examples. The present invention is not limited thereto and can be suitably changed and performed within a range in which the effects of the present invention are exhibited.

### “Method for Manufacturing Magnetoresistance Effect Element”

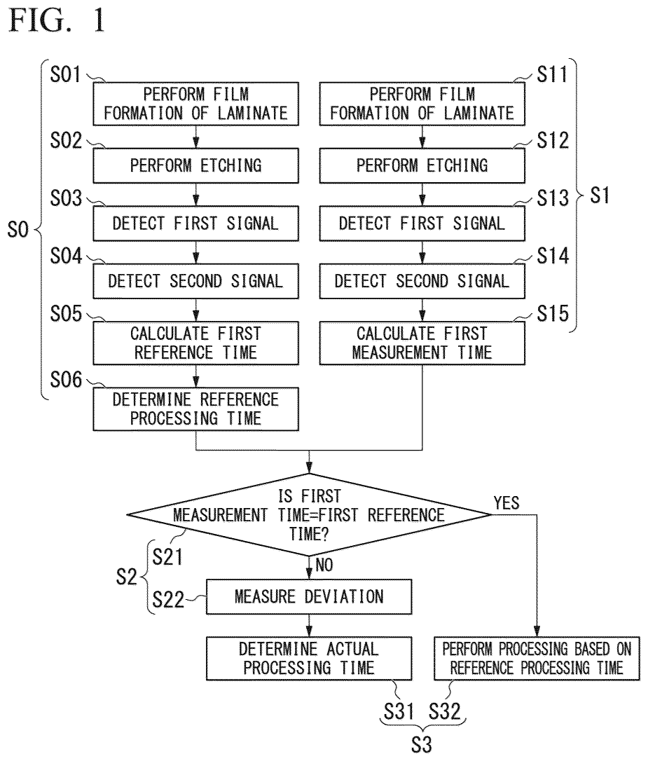

FIG. 1 is a flowchart of a method for manufacturing a magnetoresistance effect element according to a first embodiment. The method for manufacturing a magnetoresistance effect element according to the first embodiment has a preparation step S0, a measurement step S1, a comparison step S2, and a determination step S3, for example. The preparation step S0 is a separate step which is performed in advance and does not always need to be performed.

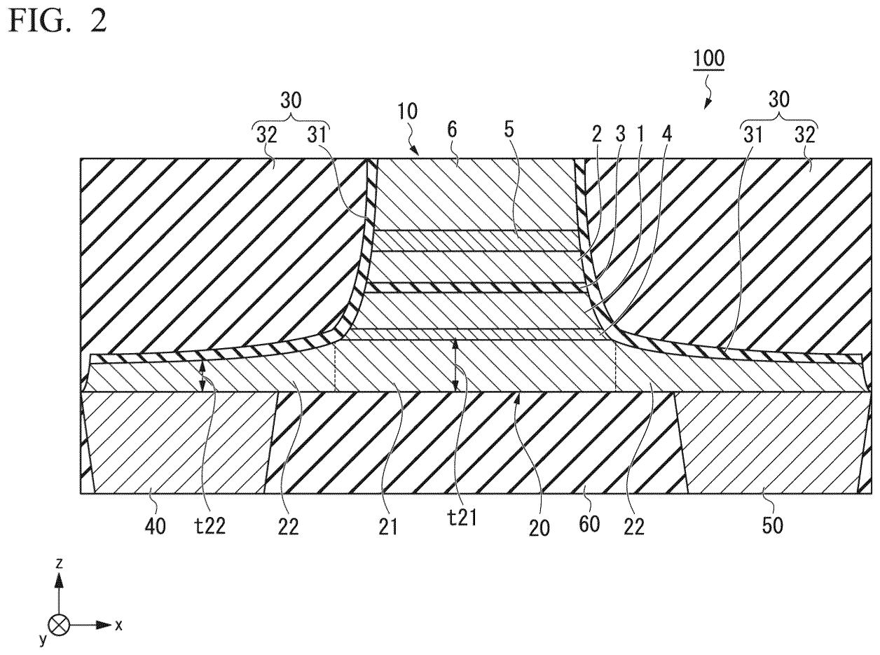

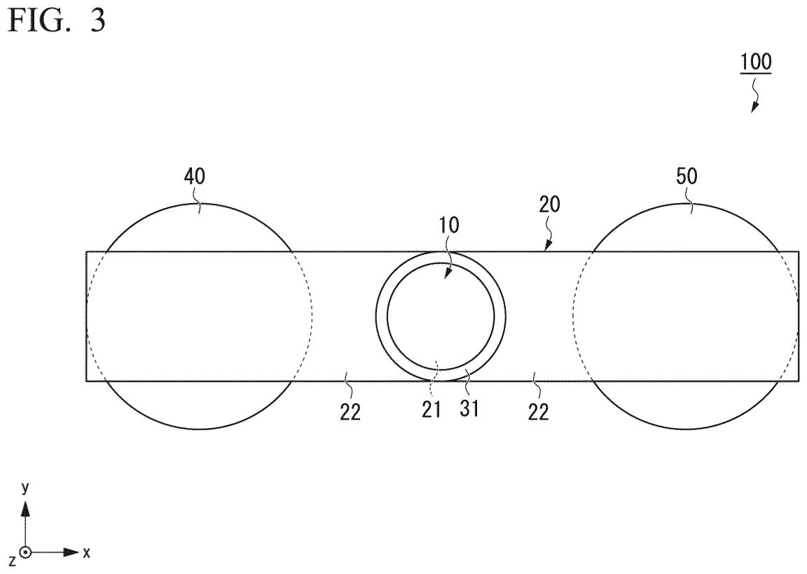

First, a magnetoresistance effect element produced by this manufacturing method will be described. FIG. 2 is a cross-sectional view of a magnetoresistance effect element 100 produced by the manufacturing method according to the first embodiment. FIG. 3 is a plan view of the magnetoresistance effect element 100 produced by the manufacturing method according to the first embodiment.

Hereinafter, a lamination direction of layers in the magnetoresistance effect element 100 will be regarded as a z direction, and a surface orthogonal to the z direction will be regarded as an xy plane. One direction in the xy plane will be regarded as an x direction, and a direction orthogonal to the x direction in the xy plane will be regarded as a y direction. For example, the x direction coincides with a direction in which a wiring layer 20 extends.

For example, the magnetoresistance effect element 100 includes a laminate 10, the wiring layer 20, side wall layers 30, a first via wiring 40, a second via wiring 50, and an insulating layer 60.

The magnetoresistance effect element 100 is a magnetic element utilizing a spin-orbit torque (SOT) and may be referred to as a spin-orbit torque-type magnetoresistance effect element, a spin injection-type magnetoresistance effect element, or a spin current magnetoresistance effect element.

The magnetoresistance effect element 100 is an element which records and saves data. The magnetoresistance effect element 100 records data by a resistance value of the laminate 10 in the z direction. The resistance value of the laminate 10 in the z direction varies when a writing current is applied along the wiring layer 20 and spins are injected into the laminate 10 from the wiring layer 20. A writing current flows along the wiring layer 20 when an electric potential difference is applied between the first via wiring 40 and the second via wiring 50. The resistance value of the laminate 10 in the z direction can be read by applying a reading current in the z direction of the laminate 10.

The laminate 10 comes into contact with the wiring layer 20. For example, the laminate 10 is laminated on the wiring layer 20.

The laminate 10 is a columnar body. For example, the shape of the laminate 10 in a plan view in the z direction is a circular shape, an oval shape, or a quadrangular shape. For example, side walls of the laminate 10 are inclined with respect to the z direction.

For example, the laminate 10 includes a first ferromagnetic layer 1, a second ferromagnetic layer 2, a barrier layer 3, a base layer 4, a cap layer 5, and a nonmagnetic layer 6. The laminate 10 may have a layer other than the first ferromagnetic layer 1, the second ferromagnetic layer 2, the barrier layer 3, the base layer 4, the cap layer 5, and the nonmagnetic layer 6. The resistance value of the laminate 10 varies in accordance with the difference in the relative angle of magnetization between the first ferromagnetic layer 1 and the second ferromagnetic layer 2 sandwiching the barrier layer 3 therebetween.

For example, the first ferromagnetic layer 1 is closer to the wiring layer 20 than the second ferromagnetic layer 2. The first ferromagnetic layer 1 may come into direct contact with the wiring layer 20 or may come into indirect contact with it with the base layer 4 therebetween. For example, the first ferromagnetic layer 1 is laminated on the wiring layer 20.

Spins are injected into the first ferromagnetic layer 1 from the wiring layer 20. The magnetization of the first ferromagnetic layer 1 receives a spin-orbit torque (SOT) by injected spins so that the orientation direction thereof varies. The first ferromagnetic layer 1 is referred to as a magnetization free layer.

The first ferromagnetic layer 1 includes a ferromagnetic body. For example, the ferromagnetic body is a metal selected from the group consisting of Cr, Mn, Co, Fe, and Ni; an alloy including one or more kinds of these metals; an alloy including at least one or more kinds of elements of these metals, B, C, and N; or the like. For example, the ferromagnetic body is an alloy of Co—Fe, Co—Fe—B, Ni—Fe, or Co—Ho; a Sm—Fe alloy; a Fe—Pt alloy; a Co—Pt alloy; or a CoCrPt alloy.

The first ferromagnetic layer 1 may include a Heusler alloy. The Heusler alloy includes an intermetallic compound having a chemical composition of XYZ or X₂YZ. X represents a transition metal element or a noble metal element of the Co group, the Fe group, the Ni group, or the Cu group on the periodic table. Y represents a transition metal of the Mn group, the V group, the Cr group, or the Ti group, or a kind of an element represented by X. Z represents a typical element of Group III to Group V. For example, the Heusler alloy consists of Co₂FeSi, Co₂FeGe, Co₂FeGa, Co₂MnSi, Co₂Mn₁₋ₐFeₐAl_{b}Si_{1-b}, Co₂FeGe_{1-c}Ga_{c}, or the like. The Heusler alloy has a high spin polarization.

The second ferromagnetic layer 2 is at a position farther from the wiring layer 20 than the first ferromagnetic layer 1. The second ferromagnetic layer 2 is sandwiched between the barrier layer 3 and the nonmagnetic layer 6. The second ferromagnetic layer 2 includes a ferromagnetic body. The orientation direction of magnetization of the second ferromagnetic layer 2 is less likely to vary than that of magnetization of the first ferromagnetic layer 1 when a predetermined external force is applied. The second ferromagnetic layer 2 is referred to as a magnetization fixed layer or a magnetization reference layer. In the laminate 10 shown in FIG. 2, the magnetization fixed layer is located on a side away from a substrate Sub and is referred to as a top pin structure. The magnetoresistance effect element according to the present embodiment may have a bottom pin structure in which the laminate 10 is closer to the substrate Sub than the wiring layer 20 and the magnetization fixed layer is closer to the substrate Sub than the magnetization free layer.

A material similar to that constituting the first ferromagnetic layer 1 is used as the material constituting the second ferromagnetic layer 2.

The second ferromagnetic layer 2 may have a synthetic antiferromagnetic structure (SAF structure). The synthetic antiferromagnetic structure is constituted of two magnetic layers sandwiching a nonmagnetic layer therebetween. The second ferromagnetic layer 2 may have two magnetic layers and a spacer layer sandwiched between these. The coercivity of the second ferromagnetic layer 2 increases due to antiferromagnetic coupling between two ferromagnetic layers. For example, the ferromagnetic layers are made of IrMn, PtMn, or the like. For example, the spacer layer includes at least one selected from the group consisting of Ru, Ir, and Rh.

The barrier layer 3 is sandwiched between the first ferromagnetic layer 1 and the second ferromagnetic layer 2. The barrier layer 3 includes a nonmagnetic body. When the barrier layer 3 is an insulator (when it is a tunnel barrier layer), for example, Al₂O₃, SiO₂, MgO, MgAl₂O₄, or the like can be used as a material thereof. In addition to these, it is also possible to use a material or the like in which a part of Al, Si, or Mg is replaced with Zn, Be, or the like. Among these, since MgO and MgAl₂O₄ are materials which can realize coherent tunneling, spins can be efficiently injected. When the barrier layer 3 is made of a metal, Cu, Au, Ag, or the like can be used as a material thereof. Moreover, when the barrier layer 3 is constituted of a semiconductor, Si, Ge, CuInSe₂, CuGaSe₂, Cu(In, Ga)Se₂, or the like can be used as a material thereof.

For example, the base layer 4 is located between the first ferromagnetic layer 1 and the wiring layer 20. The base layer 4 may be omitted.

For example, the base layer 4 includes a buffer layer and a seed layer. The buffer layer is a layer relaxing lattice mismatch between different crystals. The seed layer increases the crystallinity of a layer laminated on the seed layer. For example, the seed layer is formed on the buffer layer.

For example, the buffer layer is made of Ta (single material), TaN (tantalum nitride), CuN (copper nitride), TiN (titanium nitride), or NiAl (nickel aluminum). For example, the seed layer is made of Pt, Ru, Zr, a NiCr alloy, or NiFeCr.

The cap layer 5 is located on the second ferromagnetic layer 2. For example, the cap layer 5 increases magnetic anisotropy of the second ferromagnetic layer 2. For example, the cap layer 5 increases perpendicular magnetic anisotropy of the second ferromagnetic layer 2. For example, the cap layer 5 is made of magnesium oxide, W, Ta, Mo, or the like. For example, the film thickness of the cap layer 5 is 0.5 nm to 5.0 nm.

The nonmagnetic layer 6 is located on the cap layer 5. The nonmagnetic layer 6 is a part of a hard mask used when processing the laminate 10 at the time of manufacturing. The nonmagnetic layer 6 also functions as an electrode. For example, the nonmagnetic layer 6 includes Al, Cu, Ta, Ti, Zr, NiCr, nitrides (for example, TiN, TaN, or SiN), or oxides (for example, SiO₂).

For example, the wiring layer 20 has a length which is longer in the x direction than in the y direction when viewed in the z direction. A writing current flows in the x direction along the wiring layer 20 between the first via wiring 40 and the second via wiring 50.

The wiring layer 20 generates a spin current due to a spin Hall effect occurring when a current flows and injects spins into the first ferromagnetic layer 1. For example, the wiring layer 20 applies a spin-orbit torque (SOT) to the magnetization of the first ferromagnetic layer 1 by an amount with which the magnetization of the first ferromagnetic layer 1 can be reversed.

The spin Hall effect is a phenomenon in which a spin current is induced in a direction orthogonal to a flowing direction of a current based on a spin-orbit interaction when a current flows. The spin Hall effect is in common with a normal Hall effect in that traveling (moving) charge (electrons) can bend the traveling (moving) direction. The normal Hall effect causes the traveling direction of traveling charged particles in a magnetic field to bend by means of a Lorentz force. In contrast, the spin Hall effect causes the moving direction of spins to bend simply by means of moving electrons (flowing currents) even if there is no magnetic field.

For example, if a current flows in the wiring layer 20, first spins polarized in one direction and second spins polarized in a direction opposite to that of the first spins individually bend in a direction orthogonal to the flowing direction of a current due to the spin Hall effect. For example, the first spins polarized in the negative y direction bend in the positive z direction from the x direction that is the traveling direction thereof, and the second spins polarized in the positive y direction bend in the negative z direction from the x direction that is the traveling direction thereof.

In the nonmagnetic body (a material that is not a ferromagnetic body), the number of electrons in the first spins and the number of electrons in the second spins generated due to the spin Hall effect are the same. That is, the number of electrons in the first spins toward the positive z direction and the number of electrons in the second spins toward the negative z direction are the same. The first spins and the second spins flow in directions in which an uneven distribution of the spins is eliminated. Since flows of charge are offset each other in movement of the first spins and the second spins in the z direction, the current amount becomes zero. A spin current accompanying no current is particularly referred to as a pure spin current.

When a flow of electrons in the first spins is expressed as JT, a flow of electrons in the second spins is expressed as J_{↓}, and a spin current is expressed as J_{S}, these are defined as J_{S}=J_{↑}−J_{↓}. The spin current J_{S} is generated in the z direction. The first spins are injected into the first ferromagnetic layer 1 from the wiring layer 20.

The wiring layer 20 includes any of a metal, an alloy, an intermetallic compound, a metal boride, a metal carbide, a metal silicide, a metal phosphide, and a metal nitride having a function of generating a spin current due to the spin Hall effect occurring when a writing current flows. For example, the wiring layer 20 includes any one selected from the group consisting of a heavy metal whose atomic number is 39 or larger, a metal oxide, a metal nitride, a metal oxynitride, and a topological insulator.

For example, the wiring layer 20 includes a nonmagnetic heavy metal as a main component. A heavy metal denotes a metal having a specific gravity equal to or greater than that of yttrium (Y). For example, a nonmagnetic heavy metal is a nonmagnetic metal having d electrons or f electrons in an outermost shell and having a large atomic number (atomic number 39 or larger). For example, the wiring layer 20 is made of Hf, Ta, or W. In a nonmagnetic heavy metal, a spin-orbit interaction stronger than those in other metals occurs. A spin Hall effect occurs due to a spin-orbit interaction, and spins are likely to be unevenly distributed inside the wiring layer 20 so that the spin current J_{S} is likely to be generated.

The wiring layer 20 may further include a magnetic metal. The magnetic metal is a ferromagnetic metal or an antiferromagnetic metal. A minute amount of magnetic metal included in the nonmagnetic body becomes a scattering factor of spins. For example, a minute amount indicates 3% or smaller than the total mole ratio of the elements constituting the wiring layer 20. When spins scatter due to the magnetic metal, the spin-orbit interaction is strengthened, and generation efficiency of a spin current with respect to a current is enhanced.

The wiring layer 20 may include a topological insulator. The topological insulator is a substance in which the interior of the substance is an insulator or a high-resistance body and a spin-polarized metal state has occurred on its surface. An internal magnetic field is generated in the topological insulator due to the spin-orbit interaction. In the topological insulator, a new topological phase develops due to an effect of the spin-orbit interaction even if there is no external magnetic field. The topological insulator can generate a pure spin current with high efficiency due to the strong spin-orbit interaction and breaking of reversal symmetry at edges.

For example, the topological insulator is made of SnTe, Bi_{1.5}Sb_{0.5}Te_{1.7}Se_{1.3}, TlBiSe₂, Bi₂Te₃, Bi₁₋ₓSbₓ, (Bi₁₋ₓSbₓ)₂Te₃ or the like. The topological insulator can generate a spin current with high efficiency.

The wiring layer 20 has an overlapping portion 21 overlapping the laminate 10 when viewed in the z direction, and a non-overlapping portion 22 not overlapping the laminate 10 when viewed in the z direction. For example, a film thickness t22 of the wiring layer 20 in the non-overlapping portion 22 is smaller than a film thickness t21 of the wiring layer 20 in the overlapping portion 21. For example, the film thickness t22 of the wiring layer 20 in the non-overlapping portion 22 is equal to or larger than 66% of the film thickness t21 of the wiring layer 20 in the overlapping portion 21. For example, the thickness of the overlapping portion 21 is 3 nm or larger. For example, the thickness of the overlapping portion 21 may be 20 nm or smaller. The film thicknesses of the overlapping portion 21 and the non-overlapping portion 22 are average values of the film thicknesses measured at five different points in the x direction.

Although details will be described below, a situation in which the thickness t22 of the non-overlapping portion 22 becomes excessively small can be curbed using the method for manufacturing a magnetoresistance effect element according to the present embodiment. The material constituting the wiring layer 20 has a high resistance compared to good conductors such as Al. If the non-overlapping portion 22 is excessively small, heat is generated in the part, which may cause breaking or the like in the wiring layer 20.

The side wall layers 30 cover the side walls of the laminate 10. The side wall layers 30 are insulators. The side wall layers 30 secure electrical insulation between the laminate 10 and other constituent elements.

The side wall layers 30 include materials included in layers set as a first detection layer and a second detection layer in the laminate 10. That is, the side wall layers 30 include a first material included in the first detection layer, and a second material included in the second detection layer. For example, the side wall layers 30 include the first material and the second material inside insulating layers similar to the insulating layer 60 which will be described below. The first detection layer and the second detection layer can be arbitrarily set from the layers constituting the laminate 10. It is assumed that the first detection layer is a layer at a position farther from the wiring layer 20 than the second detection layer.

For example, when the first detection layer is set as the nonmagnetic layer 6 and the second detection layer is set as the barrier layer 3, the side wall layers 30 include the first material derived from the nonmagnetic layer 6 and the second material derived from the barrier layer 3. For example, when the nonmagnetic layer 6 is TiN and the barrier layer 3 is Mg—Al—O, the side wall layers 30 include Ti and Al.

The first material and the second material are any one selected from the group consisting of Ta, W, Mg, Ru, Si, Ir, Mn, Co, Fe, Ni, Al, O, and Ti. For example, the first material and the second material are a combination of Mg and any one selected from the group consisting of Co, Ru, Mn, Ta, Ti, and Ni; a combination of Ni and any one selected from the group consisting of Co, Fe, and Ru; a combination of Ta and any one selected from the group consisting of Co, Fe, and Ru; or a combination of Ti and any one selected from the group consisting of Co, Fe, and Ru. The first material and the second material may be the same or different.

If the side wall layers 30 include the first material and the second material, the thermal conductivity of the side wall layers 30 is improved. Heat accumulated inside the magnetoresistance effect element 100 will cause degradation in magnetization stability, fluctuation in performance of the element, or the like. Fluctuation in the range of resistance change or the like in the magnetoresistance effect element 100 can be curbed by discharging heat inside the magnetoresistance effect element 100 via the side wall layers 30.

When the first material and the second material are different, it is preferable that the concentration of the second material in the side wall layers 30 be higher than the concentration of the first material. For example, when the first material is a heavy element such as Ta or Ru, if the concentration of the second material is high, oxidation of the side wall layers is likely to proceed, and short circuits due to redeposition are unlikely to occur.

In addition, the concentrations of the first material and the second material in the side wall layers 30 may be higher at a position closer to the wiring layer 20 in the z direction than at a position farther from the wiring layer 20. If the constitution is satisfied, heat generated inside the magnetoresistance effect element 100 can be released toward the first via wiring 40 and the second via wiring 50 having a high thermal conductivity via the side wall layers 30. The magnetization stability of the magnetoresistance effect element 100 can be enhanced by releasing heat in a direction away from the first ferromagnetic layer 1 and the second ferromagnetic layer 2 having magnetization.

In addition, in the side wall layers 30, a first part surrounding an area around the layer on the wiring layer 20 side from the first detection layer may include the first material and the second material. For example, when the first detection layer is the nonmagnetic layer 6, the first part is a part surrounding an area around the first ferromagnetic layer 1, the second ferromagnetic layer 2, the barrier layer 3, the base layer 4, and the cap layer 5. Since the first material and the second material are present throughout the entire side wall layers 30, the thermal conductivity of the entire side wall layers 30 is enhanced.

For example, the side wall layers 30 may each have a first side wall layer 31 and a second side wall layer 32. The first side wall layer 31 is closer to the laminate 10 than the second side wall layer 32. The first side wall layer 31 covers the laminate 10, and the second side wall layer 32 covers the first side wall layer 31.

In this case, the first side wall layer 31 includes the first material and the second material. For example, the first side wall layer 31 is formed by adding the first material and the second material to silicon oxynitride, and the second side wall layer is formed of silicon nitride.

The first via wiring 40 is connected to a first end of the wiring layer 20. The first via wiring 40 is a columnar body. The first via wiring 40 may be formed by laminating a plurality of columnar bodies. For example, the columnar body is a circular cylinder, an elliptical cylinder, or a rectangular cylinder. The first via wiring 40 includes a conductive material.

When viewed in the z direction, the second via wiring 50 comes into contact with the wiring layer 20 at a position sandwiching the first ferromagnetic layer 1 with the first via wiring 40. The second via wiring 50 may be connected to the same surface as the surface to which the first via wiring 40 of the wiring layer 20 is connected or may be connected to a different surface. The second via wiring 50 is made of a material similar to that of the first via wiring 40.

The insulating layer 60 is an insulating layer providing insulation between wirings of a multilayer wiring or between elements. For example, the insulating layer 60 is made of silicon oxide (SiOₓ), silicon nitride (SiNₓ), silicon carbide (SiC), chromium nitride, silicon carbonitride (SiCN), silicon oxynitride (SiON), aluminum oxide (Al₂O₃), zirconium oxide (ZrOₓ), magnesium oxide (MgO), aluminum nitride (AlN), or the like.

Subsequently, a method for manufacturing the foregoing magnetoresistance effect element 100 will be described on the basis of the flowchart in FIG. 1.

First, before the magnetoresistance effect element 100 is actually produced, the preparation step S0 is performed in order to make a reference magnetoresistance effect element and determine a reference processing time. The preparation step S0 does not need to be performed every time the magnetoresistance effect element 100 is manufactured and may be performed first as a condition setting step. The preparation step S0 is a step of determining a reference for setting conditions for producing the magnetoresistance effect element 100 which will become an actual product, and the magnetoresistance effect element 100 produced in the preparation step S0 does not have to be an actual product.

The preparation step S0 has a film formation step S01, an etching step S02, a first signal detection step S03, a second signal detection step S04, a first reference time calculation step S05, and a reference processing time determination step S06.

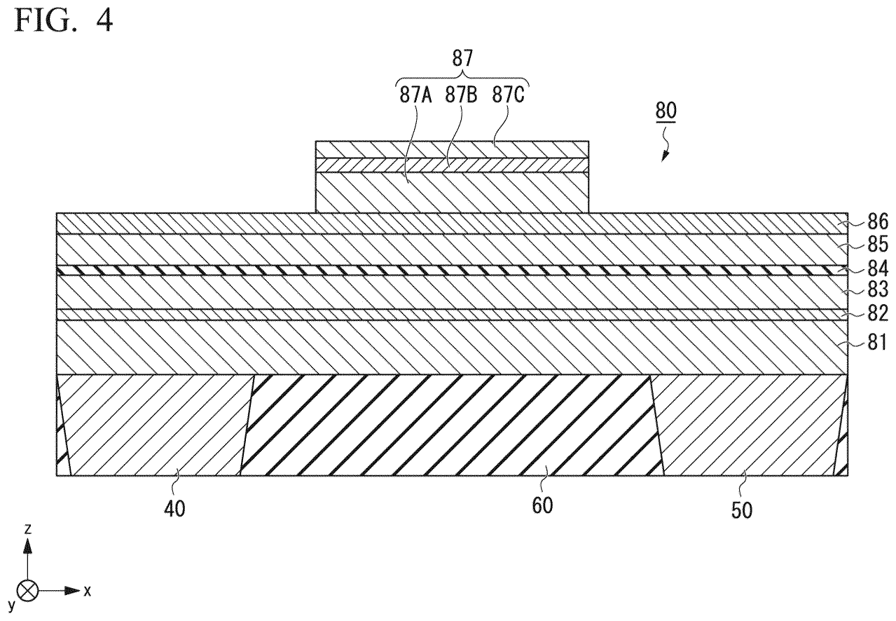

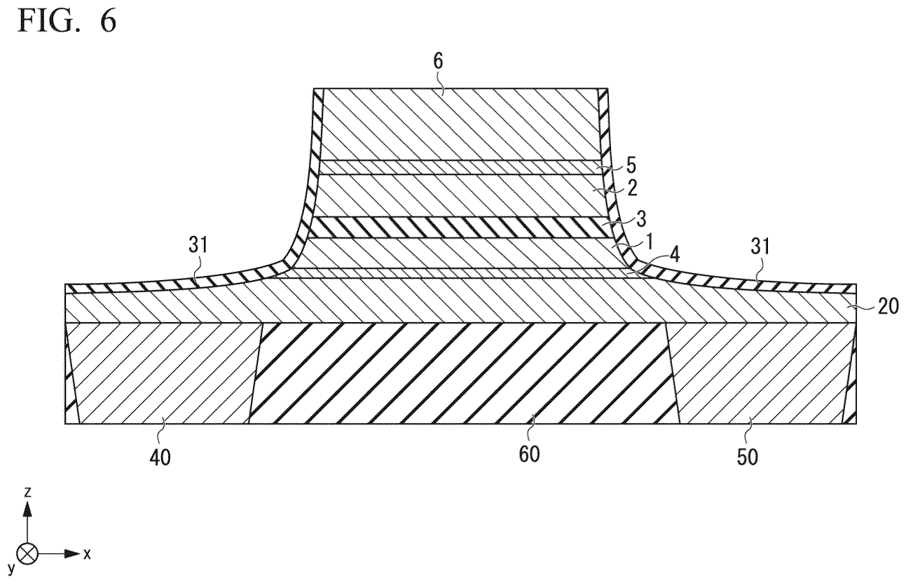

FIGS. 4 to 6 are explanatory schematic views of the method for manufacturing a magnetoresistance effect element according to the first embodiment.

In the film formation step S01, a reference laminate 80 is produced. For example, the reference laminate 80 is produced on the first via wiring 40, the second via wiring 50, and the insulating layer 60. The first via wiring 40 and the second via wiring 50 are produced by forming an opening in the insulating layer 60 and filling the inside of the opening with a conductor.

First, a wiring layer 81, a base layer 82, a first ferromagnetic layer 83, a barrier layer 84, a second ferromagnetic layer 85, and a cap layer 86 are subjected to film formation in this order. For example, film formation of each layer is performed by a sputtering method. The wiring layer 81, the base layer 82, the first ferromagnetic layer 83, the barrier layer 84, the second ferromagnetic layer 85, and the cap layer 86 respectively correspond to the wiring layer 20, the base layer 4, the first ferromagnetic layer 1, the barrier layer 3, the second ferromagnetic layer 2, and the cap layer 5 and are made of similar materials.

Subsequently, a nonmagnetic layer 87 is formed in a part of the cap layer 86. The nonmagnetic layer 87 is formed at a position where the laminate 10 is scheduled to be produced. The nonmagnetic layer 87 may have a three-layer structure including a first layer 87A, a second layer 87B, and a third layer 87C. The first layer 87A is closer to the second ferromagnetic layer 85 than the third layer 87C. The second layer 87B is sandwiched between the first layer 87A and the third layer 87C. In the nonmagnetic layer 87, the first layer 87A, the second layer 87B, and the third layer 87C are sequentially laminated in this order from the second ferromagnetic layer 85 side.

The nonmagnetic layer 87 corresponds to the nonmagnetic layer 6 and is made of a similar material. When the nonmagnetic layer 87 has a three-layer structure, for example, the first layer 87A is made of Ta, the second layer 87B is made of Ru, and the third layer 87C is made of TiN.

Subsequently, the etching step S02 is performed. For example, etching is performed by ion beam milling (IBE), reactive ion etching (RIE) method, or the like.

When the etching step S02 is performed, it is determined which layers of the reference laminate 80 are to be the first detection layer and the second detection layer. For example, the nonmagnetic layer 87 may serve as the first detection layer, and the barrier layer 84 may serve as the second detection layer. For example, as shown in FIG. 4, when the nonmagnetic layer 87 has a three-layer structure, any layer in the nonmagnetic layer 87 may serve as the first detection layer. For example, the third layer 87C may serve as the first detection layer, and the first layer 87A may serve as the second detection layer. In addition, any layer in the reference laminate 80 may further be set as a third detection layer.

The first detection layer and the second detection layer may be selected from the reference laminate 80 such that the distance between the first detection layer and the second detection layer becomes 4 nm or longer. In addition, when the third detection layer is selected as well, the third detection layer may be selected from the reference laminate 80 such that the distances between the first detection layer and the third detection layer and between the second detection layer and the third detection layer become 4 nm or longer. If the detection layers are distant from each other, signals are unlikely to be mixed into during detection. The detection accuracy of the detection device is enhanced by selecting the detection layers in this manner.

In addition, layers having a thickness of 1 nm or larger may be selected as the first detection layer and the second detection layer. In addition, when the third detection layer is selected as well, a layer having a thickness of 1 nm or larger may be selected as the third detection layer. If the thicknesses of the detection layers are sufficiently large, the time for detecting signals becomes longer. If the detection layers are selected in this manner, missing of detection by the detection device can be avoided.

In addition, the first detection layer and the second detection layer may be selected from the reference laminate 80 such that the first detection layer and the second detection layer are layers including the same material. In this case, the first material derived from the first detection layer and the second material derived from the second detection layer become the same. Since the detection sensitivity of the detection device varies depending on the material, when the first material and the second material are the same material, signals can be detected favorably without adjusting the sensitivity. In addition, when the third detection layer is selected, a layer including the same material as those of the first detection layer and the second detection layer may be selected as the third detection layer.

In addition, the first detection layer and the second detection layer may be selected from the reference laminate 80 such that the first detection layer and the second detection layer are layers including different materials. In this case, the first material derived from the first detection layer and the second material derived from the second detection layer are different. By using different materials to be detected, it become easier to judge which layer is being processed from a signal. In addition, when the third detection layer is selected, a layer including a material different from those of the first detection layer and the second detection layer may be selected as the third detection layer.

In addition, layers having the same thickness may be selected as the first detection layer and the second detection layer. For example, when the first material and the second material are the same materials, if the thicknesses of the first detection layer and the second detection layer are the same, the intensities of a first signal detected during processing of the first detection layer and a second signal detected during processing of the second detection layer substantially coincide with each other. If the intensities of detected signals substantially coincide with each other, signals are unlikely to be missed. In addition, when the third detection layer is selected, a layer having the same thickness as those of the first detection layer and the second detection layer may be selected as the third detection layer.

In addition, layers having different thicknesses may be selected as the first detection layer and the second detection layer. For example, when the first material and the second material are different materials, the detection sensitivity of the detection device may differ from each other. If the first detection layer and the second detection layer are selected such that a layer including a material having a low detection sensitivity has a large thickness and a layer including a material having a high detection sensitivity has a small thickness, the signal intensities generated during processing of respective layers will become similar. In addition, when the third detection layer is selected, a layer having a thickness different from those of the first detection layer and the second detection layer may be selected as the third detection layer.

Hereinafter, description will be given based on an example in which the first detection layer is the third layer 87C of the nonmagnetic layer 87 and the second detection layer is the barrier layer 84.

Subsequently, in the first signal detection step S03, the first signal derived from the first material included in the first detection layer is detected. The first signal can be detected by performing secondary ion mass analysis (SIMS) or solid-state optical emission spectroscopy (OES) while performing etching. For example, if etching of the reference laminate 80 is performed, first, a part of the third layer 87C and the cap layer 86 is etched. At this time, atoms constituting the third layer 87C are dispersed and detected by the detection device. For example, the detection device detects the first signal derived from the first material included in the third layer 87C.

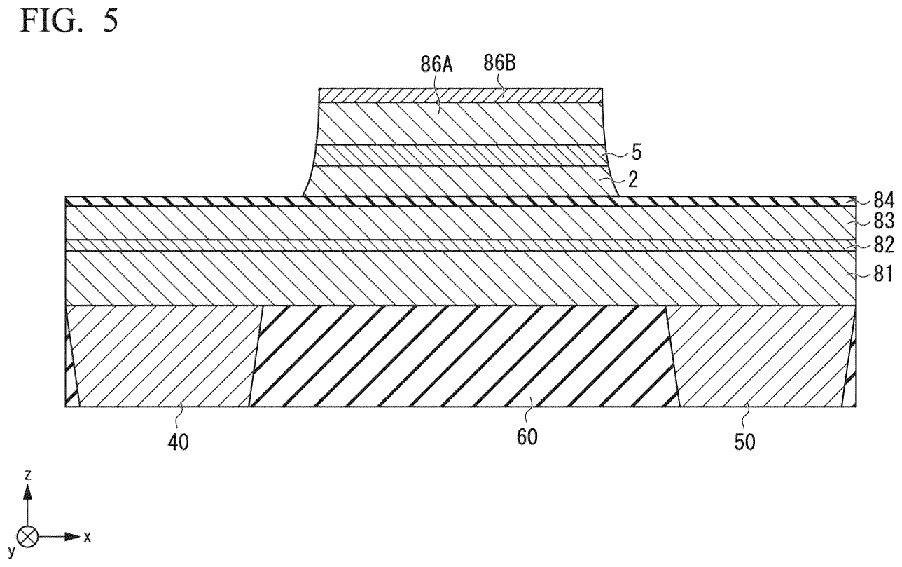

Subsequently, in the second signal detection step S04, the second signal derived from the second material included in the second detection layer is detected. The second signal can be detected by performing secondary ion mass analysis (SIMS) or solid-state optical emission spectroscopy (OES) while performing etching. For example, as shown in FIG. 5, if etching reaches the barrier layer 84, atoms constituting the barrier layer 84 are dispersed and detected by the detection device. For example, the detection device detects the second signal derived from the second material included in the barrier layer 84.

There is a time lag between detection of the first signal and detection of the second signal. In the first reference time calculation step S05, this time lag is calculated. Regarding the time when the first signal is detected, a time when the first signal reaches a predetermined intensity or higher is set as a start time. Similarly, regarding the time when the second signal is detected, a time when the second signal reaches a predetermined intensity or higher is set as a start time. The time lag is calculated by obtaining the time difference between the start time for detecting the first signal and the start time for detecting the second signal. This time lag is set as a first reference time.

In addition, when the third detection layer is set, a second reference time from detection of the first signal to detection of a third signal, and a third reference time from detection of the second signal to detection of the third signal may be obtained.

Subsequently, the reference processing time determination step S06 is performed. A reference processing time is a time from the start time for detecting the second signal to the end of etching. For example, conditions under which the film thickness t22 of the non-overlapping portion 22 becomes equal to or larger than 66% of the film thickness t21 of the overlapping portion 21 are obtained by performing an experiment in which the time from the start time for detecting the second signal to the end of etching is varied. A time satisfying the conditions is set as the reference processing time. Regarding the reference processing time, a predetermined time of an absolute value may be set or a time corresponding to a predetermined ratio to the first reference time may be set.

Subsequently, the measurement step S1 is performed. The measurement step S1 has a film formation step S11, an etching step S12, a first signal detection step S13, a second signal detection step S14, and a first measurement time calculation step S15.

In the film formation step S11, a laminate is produced under the same conditions and with the same film constitution as the reference laminate 80 produced in the film formation step S01.

Subsequently, the etching step S12 is performed. The etching conditions in the etching step S12 are the same conditions as in the etching step S02. In addition, the same layers as the layers selected in the preparation step S0 are set as the first detection layer and the second detection layer. In addition, as necessary, the same layer as the layer selected in the preparation step S0 is set as the third detection layer.

Subsequently, in the first signal detection step S13, the first signal derived from the first material included in the first detection layer is detected. For example, when etching of the laminate is performed, first, a part of the third layer and the cap layer is etched. At this time, atoms constituting the third layer are dispersed and detected by the detection device. For example, the detection device detects the first signal derived from the first material included in the third layer.

Subsequently, in the second signal detection step S14, the second signal derived from the second material included in the second detection layer is detected. For example, if etching reaches the barrier layer, atoms constituting the barrier layer are dispersed and detected by the detection device. For example, the detection device detects the second signal derived from the second material included in the barrier layer.

There is a time lag between detection of the first signal to detection of the second signal. In the first measurement time calculation step S15, similarly to the first reference time calculation step S05, this time lag is calculated. This time lag will be referred to as a first measurement time.

In addition, when the third detection layer is set, a second measurement time from detection of the first signal to detection of the third signal and a third measurement time from detection of the second signal to detection of the third signal may be obtained in the measurement step S1.

Subsequently, the comparison step S2 is performed. This step has a first step S21 of comparing the first reference time and the first measurement time, and a second step S22 of obtaining a deviation between the first reference time and the first measurement time.

In the first step S21, the first reference time and the first measurement time are compared with each other, and it is judged whether or not they coincide with each other. Since a laminate subjected to film formation under the same conditions as the reference laminate 80 is etched under the same conditions, the first reference time and the first measurement time may coincide with each other. On the other hand, even if a laminate subjected to film formation under the same conditions as the reference laminate 80 is etched under the same conditions, the first measurement time and the first reference time may not coincide with each other. This is because the etching time may vary due to various factors.

In the first step S21, when the first reference time and the first measurement time coincide with each other, there is no deviation between the first reference time and the first measurement time. Namely, it can be said that the rate of progress in etching in the reference laminate 80 and the rate of progress in etching in the laminate are substantially the same.

In the first step S21, when the first reference time and the first measurement time do not coincide with each other, the second step S22 of obtaining a deviation is performed. The deviation between the first reference time and the first measurement time can be obtained by obtaining the difference between the first reference time and the first measurement time.

In addition, when the third detection layer is used, the second reference time and the second measurement time may be compared with each other, or the third reference time and the third measurement time may be compared with each other. That is, a deviation between the second reference time and the second measurement time or a deviation between the third reference time and the third measurement time may be obtained.

Subsequently, the determination step S3 is performed. When the first reference time and the first measurement time do not coincide with each other, a first determination step S31 of the determination step S3 is performed. When the first reference time and the first measurement time coincide with each other, a second determination step S32 of the determination step S3 is performed.

In the first determination step S31, conditions for actual processing from detection of the second signal to ending of etching are determined based on the deviation between the first reference time and the first measurement time. For example, when the first measurement time is shorter than the first reference time, the conditions for actual processing are set to be shorter than the reference processing time. For example, when the first measurement time is longer than the first reference time, the conditions for actual processing are set to be longer than the reference processing time. For example, the actual processing time may be obtained by (first reference time)+{“(first reference time)−(first measurement time)”/(first reference time)×(reference processing time)}.

In the second determination step S32, the actual processing time from detection of the second signal to ending of etching is set as the reference processing time.

In addition, when the third detection layer is used, the actual processing time may be determined in the determination step S3 in consideration of a deviation between the second reference time and the second measurement time or a deviation between the third reference time and the third measurement time. The actual processing time has a more appropriate value by adding information of these deviations to the information of the deviation between the first reference time and the first measurement time and determining the actual processing time.

Subsequently, after the laminate 10 is processed on the basis of the foregoing actual processing time, the side wall layers 30 are formed to cover an area around the laminate 10. For example, the first side wall layer 31 and the second side wall layer 32 are sputtered in this order such that the laminate 10 is covered.

Before the first side wall layer 31 is subjected to film formation, impurities may be removed from side surfaces of the laminate 10. For example, when the laminate 10 is formed, particles dispersed from each layer may be redeposited on the side surfaces of the laminate 10. The redeposited particles become impurities.

The first side wall layer 31 can be formed by simultaneously sputtering the insulation material constituting the first side wall layer 31 with the first material and the second material. By the simultaneous sputtering, the first material and the second material are added to the inside of the first side wall layer 31. The second side wall layer 32 can be obtained by sputtering the insulation material constituting the second side wall layer 32.

As described above, according to the method for manufacturing a magnetoresistance effect element according to the present embodiment, it is possible to curb excessive etching of the wiring layer 20 caused by variation in the etching conditions. Since the wiring layer 20 has high resistance and is likely to generate heat, heat generation in the magnetoresistance effect element 100 can be curbed by preventing the wiring layer 20 from becoming excessively thin.

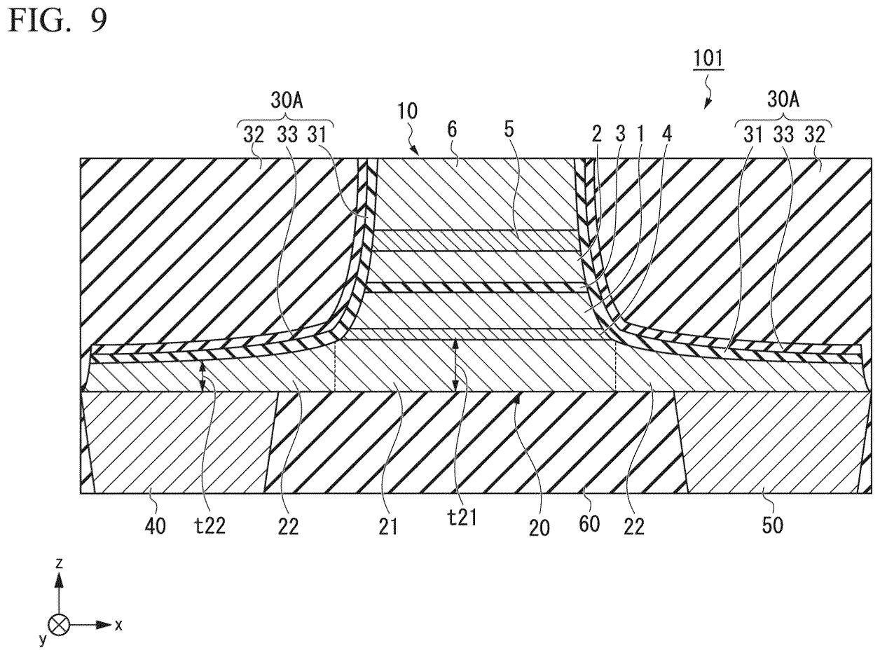

FIG. 9 is a cross-sectional view of a magnetoresistance effect element 101 according to a first modification example. The magnetoresistance effect element 101 shown in FIG. 9 differs from the magnetoresistance effect element 100 shown in FIG. 2 in that side wall layers 30A are each constituted of the first side wall layer 31, the second side wall layer 32, and a third side wall layer 33. In the magnetoresistance effect element 101, the same reference signs are applied to the same constituents as those of the magnetoresistance effect element 100, and description thereof will be omitted.

The side wall layers 30A each have the first side wall layer 31, the second side wall layer 32, and the third side wall layer 33. The first side wall layer 31 is closer to the laminate 10 than the second side wall layer 32. The third side wall layer 33 is closer to the laminate 10 than the second side wall layer 32. The third side wall layer 33 covers the first side wall layer 31 and is covered by the second side wall layer 32.

In this case, the first side wall layer 31 and the third side wall layer 33 include the first material and the second material. For example, the first side wall layer 31 and the third side wall layer 33 are formed by adding the first material and the second material to silicon oxynitride, and the second side wall layer is formed of silicon nitride.

FIG. 9 shows a case in which the side wall layers 30A include three layers, as an example, but the number of layers constituting the side wall layers 30A is not limited. For example, the first side wall layer 31 and the third side wall layer 33 may have different concentrations of the first material and the second material. If the concentrations of the first material and the second material in the side wall layers 30A become high, the insulation properties of the side wall layers 30A may be degraded. The side wall layers 30A in a multi-layer structure can enhance both the thermal conductivity and the insulation properties.

### Magnetic Array and Magnetoresistance Effect Element

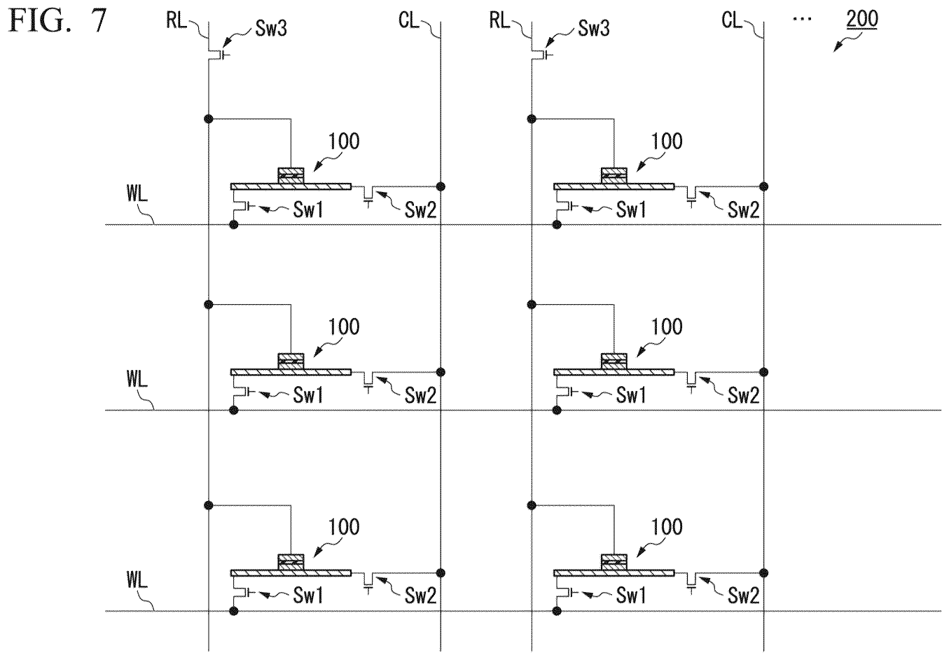

FIG. 7 is a circuit diagram of a magnetic array according to the present embodiment. A magnetic array 200 includes a plurality of magnetoresistance effect elements 100, a plurality of writing wirings WL, a plurality of common wirings CL, a plurality of reading wirings RL, a plurality of first switching elements Sw1, a plurality of second switching elements Sw2, and a plurality of third switching elements Sw3. For example, in the magnetic array 200, the magnetoresistance effect elements 100 are arrayed in a matrix shape. Each magnetoresistance effect element 100 is the foregoing magnetoresistance effect element shown in FIGS. 3 and 4.

Each of the writing wirings WL electrically connects a power source to one or more magnetoresistance effect elements 100. Each of the common wirings CL is a wiring used at times of both writing and reading data. Each of the common wirings CL electrically connects a reference electric potential to one or more magnetoresistance effect elements 100. For example, the reference electric potential is a ground potential. The common wiring CL may be provided in each of the plurality of magnetoresistance effect elements 100 or may be provided across the plurality of magnetoresistance effect elements 100. Each of the reading wirings RL electrically connects the power source to one or more magnetoresistance effect elements 100. The power source is connected to the magnetic array 200 when in use.

Each of the magnetoresistance effect elements 100 is electrically connected to each of the first switching element Sw1, the second switching element Sw2, and the third switching element Sw3. The first switching element Sw1 is connected between the magnetoresistance effect element 100 and the writing wiring WL. The second switching element Sw2 is connected between the magnetoresistance effect element 100 and the common wiring CL. The third switching element Sw3 is connected to the reading wiring RL across the plurality of magnetoresistance effect elements 100.

If a predetermined first switching element Sw1 and a predetermined second switching element Sw2 are turned on, a writing current flows between the writing wiring WL and the common wiring CL connected to a predetermined magnetoresistance effect element 100. Due to a writing current flowing therethrough, data is written in the predetermined magnetoresistance effect element 100. If a predetermined second switching element Sw2 and a predetermined third switching element Sw3 are turned on, a reading current flows between the common wiring CL and the reading wiring RL connected to a predetermined magnetoresistance effect element 100. Due to a reading current flowing therethrough, data is read from the predetermined magnetoresistance effect element 100.

The first switching elements Sw1, the second switching elements Sw2, and the third switching elements Sw3 are elements for controlling a flow of a current. For example, the first switching elements Sw1, the second switching elements Sw2, and the third switching elements Sw3 are transistors, elements such as ovonic threshold switches (OTS) utilizing phase change in a crystal layer, elements such as metal insulator transfer (MIT) switches utilizing variation in a band structure, elements such as Zener diodes and avalanche diodes utilizing a breakdown voltage, or elements whose conductivity varies in accordance with variation in atom positions.

In the magnetic array 200 shown in FIG. 7, the magnetoresistance effect elements 100 connected to the same reading wiring RL share the third switching element Sw3. The third switching element Sw3 may be provided in each of the magnetoresistance effect elements 100. In addition, the third switching element Sw3 may be provided in each of the magnetoresistance effect elements 100, and the first switching element Sw1 or the second switching element Sw2 may be shared by the magnetoresistance effect elements 100 connected to the same wiring.

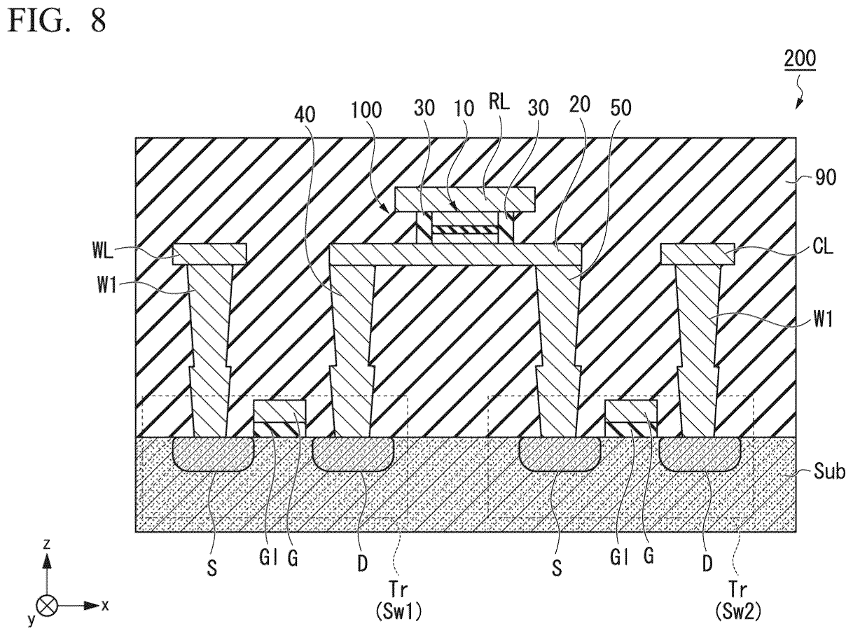

FIG. 8 is a cross-sectional view of a characteristic part of the magnetic array 200 according to the first embodiment. FIG. 8 is a cross section of the magnetoresistance effect element 100 cut along an xz plane passing through the center of the width of the wiring layer 20 (which will be described below) in the y direction.

The first switching element Sw1 and the second switching element Sw2 shown in FIG. 8 are transistors Tr. The third switching element Sw3 is electrically connected to the reading wiring RL and is located, for example, at a different position in the y direction in FIG. 8. For example, the transistors Tr are field effect transistors and have a gate electrode G, a gate insulating film GI, and a source S and a drain D formed on the substrate Sub. The source S and the drain D are prearranged depending on the flowing direction of a current, and these are the same regions. The positional relationship between the source S and the drain D may be reversed. For example, the substrate Sub is a semiconductor substrate.

The transistors Tr and the magnetoresistance effect elements 100 are electrically connected via the first via wirings 40 and the second via wirings 50. In addition, each of the transistors Tr is connected to the writing wiring WL or the common wiring CL via a via wiring W1. For example, each of first via wirings 40, the second via wirings 50, and the via wirings W1 extends in the z direction. Each of the first via wirings 40, the second via wirings 50, and the via wiring W1 may be a wiring in which a plurality of columnar bodies are laminated.

Areas around the magnetoresistance effect elements 100 and the transistors Tr are covered by an insulating layer 90. The insulating layer 60 described above is a part of the insulating layer 90. The insulating layer 90 is an insulating layer providing insulation between wirings of a multilayer wiring or between elements. For example, the insulating layer 90 is made of silicon oxide (SiOₓ), silicon nitride (SiNₓ), silicon carbide (SiC), chromium nitride, silicon carbonitride (SiCN), silicon oxynitride (SiON), aluminum oxide (Al₂O₃), zirconium oxide (ZrOₓ), magnesium oxide (MgO), aluminum nitride (AlN), or the like.

In each of the magnetoresistance effect elements 100 which belongs to the magnetic array 200, the film thickness t22 of the non-overlapping portion 22 of the wiring layer 20 is equal to or larger than 66% of the film thickness t21 of the overlapping portion 21.

By using the method for manufacturing the magnetoresistance effect element 100 according to the present embodiment, the etching conditions can be adjusted every time each of the magnetoresistance effect elements 100 which belongs to the magnetic array 200 is produced. For this reason, even when a plurality of magnetoresistance effect elements 100 are integrated, it is possible to avoid a situation in which the film thickness t22 of the non-overlapping portion 22 of the wiring layer 20 becomes extremely small in any of the magnetoresistance effect elements 100.

Thus far, preferable aspects of the present disclosure have been described as examples using the first exemplary embodiment, but the present disclosure is not limited to the embodiment. For example, characteristic constituents in each embodiment may be applied to other embodiments and modification examples.

### REFERENCE SIGNS LIST

1, 83 First ferromagnetic layer
2, 85 Second ferromagnetic layer
3, 84 Barrier layer
4, 82 Base layer
5, 86 Cap layer
6, 87 Nonmagnetic layer
10 Laminate
20, 81 Wiring layer
21 Overlapping portion
22 Non-overlapping portion
30, 30A Side wall layer
31 First Side wall layer
32 Second Side wall layer
33 Third side wall layer
40 First via wiring
50 Second via wiring
60, 90 Insulating layer
80 Reference laminate
87A First layer
87B Second layer
87C Third layer
100, 101 Magnetoresistance effect element
200 Magnetic array
S0 Preparation step
S01, S11 Film formation step
S02, S12 Etching step
S03, S13 First signal detection step
S04, S14 Second signal detection step
S05 First reference time calculation step
S15 First measurement time calculation step
S06 Reference processing time determination step
S1 Measurement step
S2 Comparison step
S21 First step
S22 Second step
S3 Determination step
S31 First determination step
S32 Second determination step

What is claimed is:

1. A method for manufacturing a magnetoresistance effect element, the method comprising:
a measurement step of etching a laminate including a first detection layer and a second detection layer, and measuring a first measurement time from detection of a first signal derived from a first material included in the first detection layer to detection of a second signal derived from a second material included in the second detection layer;
a comparison step of comparing a first reference time from detection of the first signal to detection of the second signal during etching of a reference laminate having the same film constitution as the laminate with the first measurement time, and obtaining a deviation between the first reference time and the first measurement time; and
a determination step of determining conditions from detection of the second signal to ending of etching using the deviation.

2. The method for manufacturing a magnetoresistance effect element according to claim 1,
wherein the first material and the second material are different.

3. The method for manufacturing a magnetoresistance effect element according to claim 1,
wherein the first material and the second material are the same.

4. The method for manufacturing a magnetoresistance effect element according to claim 1,
wherein the laminate has a wiring layer, a first ferromagnetic layer, a barrier layer, a second ferromagnetic layer, and a nonmagnetic layer in this order in a lamination direction,
the nonmagnetic layer is the first detection layer, and
the barrier layer is the second detection layer.

5. The method for manufacturing a magnetoresistance effect element according to claim 1,
wherein the laminate has a wiring layer, a first ferromagnetic layer, a barrier layer, a second ferromagnetic layer, and a nonmagnetic layer in this order in a lamination direction,
the nonmagnetic layer has a first layer, a second layer, and a third layer in this order from the second ferromagnetic layer side,
the third layer of the nonmagnetic layer is the first detection layer, and
the first layer of the nonmagnetic layer is the second detection layer.

6. The method for manufacturing a magnetoresistance effect element according to claim 1,
wherein a distance between the first detection layer and the second detection layer is 4 nm or longer.

7. The method for manufacturing a magnetoresistance effect element according to claim 1,
wherein a thickness of the first detection layer and a thickness of the second detection layer are different.

8. The method for manufacturing a magnetoresistance effect element according to claim 1,
wherein a thickness of the first detection layer and a thickness of the second detection layer are the same.

9. The method for manufacturing a magnetoresistance effect element according to claim 1,
wherein both a thickness of the first detection layer and a thickness of the second detection layer are 1 nm or longer.

10. The method for manufacturing a magnetoresistance effect element according to claim 1,
wherein the laminate and the reference laminate further have a third detection layer,
the measurement step further has a step of measuring a second measurement time from detection of the first signal to detection of a third signal derived from a third material included in the third detection layer, or a third measurement time from detection of the second signal to detection of the third signal, and
the comparison step further has a step of comparing a second reference time from detection of the first signal to detection of the third signal during etching of the reference laminate with the second measurement time, or a step of comparing a third reference time from detection of the second signal to detection of the third signal during etching of the reference laminate with the third measurement time.

11. A magnetoresistance effect element comprising:
a wiring layer;
a laminate; and
side wall layers,
wherein the laminate comes into contact with the wiring layer,
the laminate has a first ferromagnetic layer, a barrier layer, a second ferromagnetic layer, and a nonmagnetic layer,
the side wall layers cover side walls of the laminate,
the first ferromagnetic layer is closer to the wiring layer than the second ferromagnetic layer,
the barrier layer is sandwiched between the first ferromagnetic layer and the second ferromagnetic layer,
the second ferromagnetic layer is sandwiched between the barrier layer and the nonmagnetic layer,
the side wall layers each include a first material included in a first detection layer of the laminate, and a second material included in a second detection layer of the laminate, and
the first material and the second material are any one selected from the group consisting of Ta, W, Mg, Ru, Si, Ir, Mn, Co, Fe, Ni, Al, O, and Ti.

12. The magnetoresistance effect element according to claim 11,
wherein the side wall layers each have a first side wall layer and a second side wall layer,
the first side wall layer is closer to the laminate than the second side wall layer,
the first side wall layer is formed by adding the first material and the second material to silicon oxynitride, and
the second side wall layer is formed of silicon nitride.

13. The magnetoresistance effect element according to claim 11,
wherein the second detection layer is closer to the wiring layer than the first detection layer, and
in the side wall layers, a concentration of the second material is higher than a concentration of the first material.

14. The magnetoresistance effect element according to claim 11,
wherein the wiring layer has an overlapping portion overlapping the laminate and a non-overlapping portion not overlapping the laminate when viewed in a lamination direction, and
a film thickness of the wiring layer in the non-overlapping portion is equal to or larger than 66% of a film thickness of the wiring layer in the overlapping portion.

15. A magnetic array comprising:
a plurality of magnetoresistance effect elements,
wherein each of the plurality of magnetoresistance effect elements is the magnetoresistance effect element according to claim 11.

16. The manufacturing method according to claim 1 further comprising:
a step of forming side wall layers covering the laminate,
wherein the side wall layers each have a first side wall layer and a second side wall layer,
the first side wall layer is closer to the laminate than the second side wall layer, and
the first material and the second material are added to the second side wall layer.

17. The manufacturing method according to claim 11,
wherein the side wall layers each have a first side wall layer and the second side wall layer,
the first side wall layer is closer to the laminate than the second side wall layer, and
the second side wall layer includes the first material and the second material.

18. The manufacturing method according to claim 11,
wherein a first part of the side wall layers covering an area around a layer on the wiring layer side from the first detection layer includes the first material and the second material.
